(19) United States
(12) Patent Application Publication
(10) Pub. No.: US 2014/0063974 A1
(43) Pub. Date: Mar. 6, 2014

(54) NON-VOLATILE MEMORY DEVICE, METHOD FOR CONTROLLING THE SAME, AND DATA PROCESSING SYSTEM USING THE CONTROL METHOD

(71) Applicant: SK HYNIX INC., Icheon-si (KR)

(72) Inventor: Chul Woo YANG, Yongin-si (KR)

(73) Assignee: SK HYNIX INC., Icheon-si (KR)

(21) Appl. No.: 13/722,813

(22) Filed: Dec. 20, 2012

(30) Foreign Application Priority Data
Aug. 28, 2012 (KR) 10-2012-0094226

(51) Int. Cl. G11C 16/08

(52) U.S. Cl. CPC G11C 16/08
USPC 365/185.23; 365/185.18

(57) ABSTRACT

A non-volatile memory device, a method for controlling the same, and a data processing system using the device and method are disclosed, which relates to a technology for controlling operations of a flash memory device. The non-volatile memory device comprises a cell array configured to comprise a plurality of cells coupled between a word line and a bit line; a drive controller configured to calculate a constant value corresponding to variation in word-line resistance values measured at individual word-line positions, combine the constant value with a word-line address, and set a rising time of the word line; and a voltage provider configured to provide a bias voltage in response to the rising time set in the drive controller.

### CROSS-REFERENCE TO RELATED APPLICATION

The priority of Korean patent application No. 10-2012-0094226 filed on Aug. 28, 2012, the disclosure of which is hereby incorporated in its entirety by reference, is claimed.

### BACKGROUND OF THE INVENTION

Embodiments of the present invention relate to a non-volatile memory device, a method for controlling the same, and a data processing system using the non-volatile memory device, and more particularly to a technology for controlling operations of a flash memory device.

Semiconductor memory devices capable of storing data therein are generally classified into random access memory (RAM) devices or read only memory (ROM) devices.

Data stored in the RAM device is lost when power supply is stopped, so that the RAM device is referred to as a volatile memory device. Although the volatile memory device is configured to read/write data at a high speed, it has a disadvantage in that the stored data is lost when not powered.

On the other hand, data stored in the ROM device is not lost even when power supply is stopped. Thus, the ROM device is referred to as a non-volatile memory device. Therefore, the non-volatile memory device is used to preserve data irrespective of whether or not power is supplied thereto.

There are a variety of non-volatile memory devices. Examples include a mask read-only memory (MROM) device, a programmable read-only memory (PROM) device, an erasable programmable read-only memory (EPROM) device, an electrically erasable programmable read-only memory (EEPROM) device, etc.

From among the above-mentioned non-volatile memory devices, a system has difficulty in reading/writing data stored in each of the MROM, PROM and EPROM devices, such that general users may also have difficulty in updating data or contents stored in such non-volatile memory devices. Meanwhile, it is possible to electrically erase/write data from/in the EEPROM device, such that an application range of the EEPROM device has been rapidly extended to system programming to be continuously updated. Accordingly, the EEPROM device can be used as an auxiliary memory device.

A flash memory device has a higher degree of integration than a conventional EEPROM device, so that the flash memory device can be easily applied to a high-capacity auxiliary memory device. Among flash memory devices, a NAND-type flash memory device has a much higher degree of integration than other flash memory devices.

A flash memory device serving as a non-volatile memory device is characterized in that writing and erasing of data are electrically performed. A memory cell array of the flash memory device is composed of a plurality of blocks, and each of the blocks is composed of a plurality of pages. A block is used as a minimum unit for erasing data stored in the memory cell array.

During a program or erase operation, the flash memory device may use not only a tunneling effect based on a high-energy barrier but also a hot carrier effect generated when hot carriers having high kinetic energy pass through an insulation material.

When programming the flash memory device, a pass voltage Vpass is applied to a program-prohibited word line and a program voltage Vpgm is applied to a word line to be programmed.

In more detail, the program voltage Vpgm and the pass voltage Vpass generated by a voltage provider are applied to a global word line, and a voltage applied to the global word line is applied to a local word line through a block switch driven by a block selection signal.

The local word line includes a resistance component R and a capacitance component C. Parasitic components, i.e. RC components, contained in individual local word lines may be different from one another. Therefore, a point of time at which the program voltage is applied to a word line to be programmed is determined by considering a word line that is the most affected by parasitic components, i.e., RC components thereof.

This means that, even when a word line having a short rising time to a program voltage is selected in a program mode, the program voltage is applied to the selected word line according to a program-voltage applying time for a word line having the longest rising time to the program voltage.

The program-voltage applying time is one of factors for deciding performance or throughput of a non-volatile memory device. Thus, there is a need to develop a method for reducing the program-voltage applying time.

### BRIEF SUMMARY OF THE INVENTION

Various embodiments of the present invention are directed to providing a non-volatile memory device, a method for controlling the same, and a data processing system using the non-volatile memory device, which substantially obviate one or more problems due to limitations and disadvantages of the related art.

An embodiment of the present invention relates to a two-dimensional (2D) or three-dimensional (3D) flash memory device in which a resistance value changing according to a location of a word line is determined as a constant or invariable value, and then the constant or invariable value is combined with a word line address to set an optimum rising time of the word line.

An embodiment of the present invention relates to a 2D or 3D flash memory device in which a resistance value changing according to a location of a drain selection line is determined as a constant or invariable value, and then the constant or invariable value is combined with a drain selection address to set an optimum rising time of the drain selection line.

An embodiment of the present invention relates to a 2D or 3D flash memory device in which a resistance value changing according to a location of a source selection line is determined as a constant or invariable value, and then the constant or invariable value is combined with a source selection address to set an optimum rising time of the source selection line.

In accordance with one embodiment of the present invention, a non-volatile memory device comprises: a cell array comprising a plurality of cells each of which is coupled to and disposed between a word line and a bit line; a drive controller configured to secure a constant value corresponding to a selected word line, which is determined by detecting a variation in word-line resistance values measured according to locations of word lines in the cell array, and set a rising time of the selected word line using the constant value; and a voltage provider configured to provide the selected word line with a bias voltage obtained in response to the rising time set in the drive controller.

In accordance with another embodiment of the present invention, a non-volatile memory device comprises: a cell array comprising a plurality of cells coupled to drain selection lines; a drive controller configured to secure a constant value corresponding to a selected drain selection line, which is determined by detecting a variation in data-selection-line resistance values measured according to locations of the drain selection line, and set a rising time of the selected drain selection line using the constant value; and a voltage provider configured to provide the selected drain selection line with a bias voltage obtained in response to the rising time set in the drive controller.

In accordance with another embodiment of the present invention, a non-volatile memory device comprises: a cell array comprising a plurality of cells each coupled to a corresponding source selection line; a drive controller configured to secure a constant value corresponding to a selected source selection line, which is determined by detecting a variation in source-selection-line resistance values measured according to locations of the source-selection-line, and setting a rising time of the selected source selection line using the constant value; and a voltage provider configured to provide the selected source selection line with a bias voltage obtained in response to the rising time set in the drive controller.

In accordance with another embodiment of the present invention, a method for controlling a non-volatile memory device comprises: measuring a word-line resistance value for each of word-lines disposed at difference location, and calculating a constant value of each of the word lines by detecting a variation in the word-line resistance values; setting a rising time of a selected word line by matching an address for the selected word line with a corresponding constant value and combining the corresponding constant value with a predetermined rising time; and providing a bias voltage corresponding to the selected word line to a cell array in response to the set rising time.

In accordance with another embodiment of the present invention, a method for controlling a non-volatile memory device comprises: measuring a data-selection-line resistance value for each of drain selection lines disposed at different locations, and calculating a constant value of each of the drain selection lines by detecting a variation in the data-selection-line resistance values; setting a rising time of a selected drain selection line by matching an address for the selected drain selection line with a corresponding constant value and combining the corresponding constant value with a predetermined rising time; and providing a bias voltage corresponding to the selected drain selection line to a cell array in response to the set rising time.

In accordance with another embodiment of the present invention, a method for controlling a non-volatile memory device comprises: measuring a source-selection-line resistance value for each source-selection-line position, and calculating a constant value corresponding to a change of source-selection-line resistance values; setting a rising time of the source selection line by combining the constant value with a source selection address; and providing a bias voltage corresponding to the source selection line of a cell array in response to the set rising time.

In accordance with another embodiment of the present invention, a data processing system comprises: a host device; a non-volatile memory device coupled to the host device through a host interface, wherein the non-volatile memory device comprises a controller which calculates a constant value corresponding to a change of word-line resistance values measured at individual word-line positions, set a rising time of the word line by combining the constant value with a word-line address, and provides a bias voltage in response to the set rising time.

It is to be understood that both the foregoing general description and the following detailed description of the present invention are exemplary and explanatory and are intended to provide further explanation of the invention as claimed.

### BRIEF DESCRIPTION OF THE DRAWINGS

FIG. 1 is a block diagram illustrating a non-volatile memory device according to an embodiment of the present invention.

FIGS. 2 and 3 illustrate structural views of a non-volatile memory device according to an embodiment of the present invention.

FIGS. 4 to 6 are flowcharts illustrating methods for controlling a non-volatile memory device according to embodiments of the present invention.

FIG. 7 is a block diagram illustrating a data processing system configured to use a non-volatile memory device according to an embodiment of the present invention.

### DESCRIPTION OF EMBODIMENTS

Reference will now be made in detail to embodiments of the present invention, examples of which are illustrated in the accompanying drawings. Wherever possible, the same reference numbers will be used throughout the drawings to refer to the same or like parts.

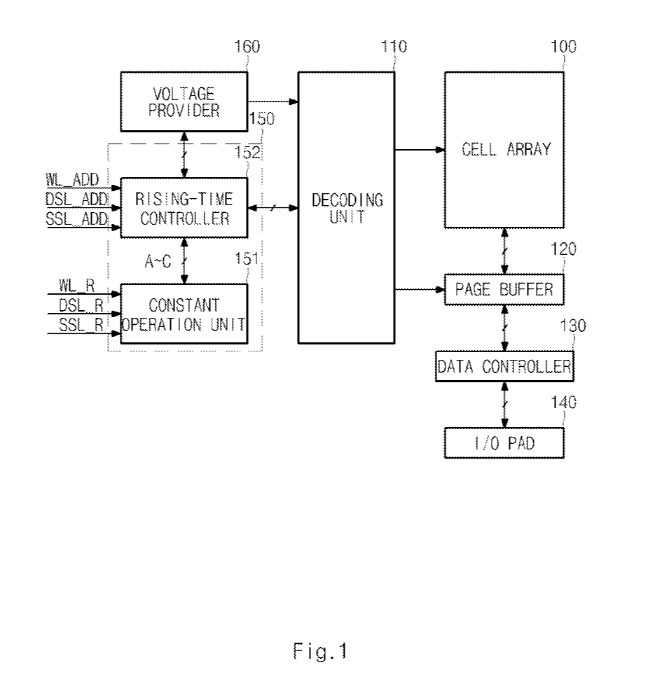

FIG. 1 is a block diagram illustrating a non-volatile memory device according to an embodiment of the present invention. Referring to FIG. 1, the non-volatile memory device comprises a cell array 100, a decoding unit 110, a page buffer 120, a data controller 130, an input/output (I/O) pad 140, a drive controller 150, and a voltage provider 160.

In an embodiment, the drive controller 150 comprises a constant operation unit 151 and a rising-time controller 152.

Although in FIG. 1, the rising-time controller 152 and the constant operation unit 151 are separate from each other, in accordance with another embodiment, the constant operation unit 151 may be located within the rising-time controller 152.

The cell array 100 comprises at least one plane comprising a bank. For example, the cell array 100 may comprise flash memory cells. In addition, the cell array 100 comprises a plurality of memory blocks coupled to bit lines and word lines. Each memory block comprises a plurality of cell strings.

The decoding unit 110 may comprise a block decoder, a block selection switch, a row decoder, and a column decoder. The decoding unit 110 receives an address from the rising-time controller 152 to select a word line or a bit line of a corresponding memory block.

For example, if a certain memory block is enabled by a block selection switch, lines, e.g., word lines, contained in the certain memory block are coupled to global lines, e.g., global word lines, each receiving an operation voltage. In an embodiment, the operation voltage provided to the global lines is output from the voltage provider 160.

The page buffer 120 is coupled to a bit line of the cell array 100 so that it operates as a write driver or a sense-amplifier according to an operation mode. The page buffer 120 operates in response to a decoding result of a column address output from the decoding unit 110. As a result, the page buffer 120 can transmit and receive data to and from the data controller 130.

The page buffer 120 controls a sensing operation and a program operation of the cell array 100. For example, the page buffer 120 operates as the sense-amplifier during a read mode, i.e., the sensing operation, and operates as the write driver during a program mode, i.e., the program operation.

Upon receiving an I/O control signal, the data controller 130 controls data I/O operations between the memory device and an external node. The data controller 130 exchanges I/O data with the external node through the I/O pad 140.

In an embodiment, the data controller 130 transmits data read out of the cell array 100 to the external node through the I/O pad 140. The data controller 130 transmits data received through the I/O pad 140 from the external node to the page buffer 120. Program data received from the I/O pad 140 is transferred through the data controller 130 and stored in a program-data latch of the page buffer 120.

The voltage provider 160 comprises at least one pump to provide a high voltage for each operation mode of the memory device. The high voltage generated from the voltage provider 160 is applied to a block in the cell array 100, which is selected by the decoding unit 110.

The constant operation unit 151 calculates constant values A˜C according to variations of a word-line (WL) resistance value WL_R, a drain-selection-line (DSL) resistance value DSL_R, and a source-selection-line (SSL) resistance value SSL_R, respectively, and provides the constant values A˜C to the rising-time controller 152.

Herein, the cell array 100 comprises numerous word lines to select a row line, and has different WL resistance values WL_R according to where the word lines are located. That is, a WL resistance value WL_R changes depending on how close the word line is to a drain selection line or a source selection line in a cell string of the cell array 100.

The cell array 100 comprises numerous drain selection lines DSLs and numerous source selection lines SSLs to select cell strings therein. A DSL or SSL resistance value DSL_R or SSL_R changes according to whether a drain selection line or a source selection line is closer to either an edge or center region of a chip.

Therefore, the constant operation unit 151 measures WL resistance values WL_R of word lines, detects a variation in the measured WL resistance values WL_R, and calculates a constant value A corresponding to each of the measured WL resistance values WL_R. In this case, it is assumed that the WL resistance values WL_R of the word lines linearly changes according to locations of the word lines with respect to a corresponding drain selection line or source selection line. For instance, as the word lines become further away from the corresponding drain selection line or source selection line, the WL resistance values WL_R of the word lines may linearly increase. A value of the constant value A also increases in response to the increased WL resistance value WL_R.

The constant operation unit 151 measures DSL resistance values DSL_R of drain selection lines and SSL resistance values SSL_R of source selection lines, detects a variation in the DSL resistance values DSL_R and a variation in the SSL resistance values SSL_R, and calculates constant values B and C corresponding to the measured resistance values DSL_R and SSL_R. It is assumed that the DSL and SSL resistance values DSL_R and SSL_R linearly change according to locations of the drain selection lines and the source selection lines. For instance, as the drain selection lines or the source selection lines become further away from the center region of the chip, the DSL or SSL resistance values DSL_R or SSL_R may linearly increase. In accordance with another embodiment, the DSL or SSL resistance values DSL_R or SSL_R may linearly increase as the drain selection lines or the source selection lines become further away from the edge region of the chip. As the DSL or SSL resistance value increases, its corresponding constant value B or C also increases.

The rising-time controller 152 receives a control signal, a command signal, and an address from an external node and generates an internal command signal. In addition, the rising-time controller 152 generates an internal address on the basis of the external address, and provides the internal address to the decoding unit 110.

In an embodiment, the external address may comprise a word line address WL_ADD, a drain selection address DSL_ADD and a source selection address SSL_ADD.

The rising-time controller 152 matches the constant values A˜C received from the constant operation unit 151 to the word line address WL_ADD, the drain selection address DSL_ADD and the source selection address SSL_ADD, respectively. As a result, the rising-time controller 152 can control respective rising times of the word line, the drain selection line, and the source selection line.

In more detail, the constant operation unit 151 detects different WL resistance values WL_R of word lines during a test mode, calculates a constant value A corresponding to each of the WL resistance values WL_R, and manages the calculated results using a reference table. Each of the constant values A stored in the reference table may be determined based on a WL resistance value WL_R according to the location of each word line, and may be estimated (e.g., offset) and calculated during the test mode.

That is, word lines are sequentially selected in the test mode, and a pass voltage Vpass is applied to the selected word line. If a voltage level of the selected word line reaches a target voltage level, a time slope at the target voltage level after the pass voltage Vpass is applied to the selected word line is calculated to determine a constant value A corresponding to the selected word line.

Upon receiving an address and a program command from the external node, a constant value A for a selected word line corresponding to the address is obtained from the reference table. The constant value A is provided to the rising-time controller 152, such that the rising-time controller 152 sets a corresponding rising time and provides the set rising time to the voltage provider 160.

Although the above-mentioned embodiment has exemplarily disclosed that the constant values A˜C obtained in the test mode are stored in the reference table, the scope and spirit of the present invention are not limited thereto. The constant values A˜C may be stored in another storage unit, such as a register, in such a manner that the stored constant values A˜C may be used.

In response to the rising time received from the rising-time controller 152, the voltage provider 160 provides a bias voltage. The bias voltage corresponds to the rising time according to the location of the selected word line after a voltage level of the selected word line has reached the pass voltage Vpass. The voltage provider 160 provides different bias voltages to word lines according to locations of the word lines.

In response to the rising time, the voltage provider 160 provides different bias voltages to the cell array 100 through the decoding unit 110 according to the location of each drain selection line or each source selection line after the voltage level of the selected word line has reached the pass voltage Vpass.

That is, the voltage provider 160 may change a drive voltage or a verification voltage of the decoding unit 110 during the program mode according to the rising time received from the rising-time controller 152.

Meanwhile, since enhancement of the integration degree of a 2D memory device in which a single-layered memory device is formed over a substrate is limited, a 3D non-volatile memory device in which memory cells are stacked in a vertical direction from the substrate has recently been introduced.

In accordance with an embodiment of the present invention, the cell array 100 may comprise memory cells stacked in a vertical direction from a substrate to implement a 3D memory device.

In a general non-volatile memory device having a 3D structure, a specific point where a maximum resistance value of a word line is achieved may be set as a target value. However, if different word-line resistance values are acquired according to physical locations of word lines, an increment step pulse program (ISPP) step or a program time may be changed according to the locations of the word lines.

A multi-level cell capable of being programmed by a plurality of threshold voltage levels has recently been developed to further improve data storage capacity of the memory device. Compared to the multi-level cell, a memory cell capable of being programmed by a single threshold voltage level is referred to as a single-level cell.

The larger the number of threshold voltage levels capable of being assigned to the multi-level cell, the higher the data storage capacity of the memory device. If a plurality of memory cells is programmed by a specific threshold voltage level, threshold voltages of the plurality of memory cells may not be identical to each other and may be distributed to a variety of levels.

In addition, an interval between neighboring or contiguous threshold voltages used for programming the multi-level cell becomes smaller as the degree of integration of the memory device increases. Accordingly, a memory device according to an embodiment of the present invention is designed to increase the reliability of data by reducing a width of threshold voltage distribution of memory cells. For this purpose, various methods have been developed, and a representative one of the methods is an increment step pulse program (ISPP) scheme.

According to the ISSP scheme, a program voltage increases and is applied in units of a step voltage starting from a predetermined voltage. In addition, a program verification operation is carried out after each program operation is completed, so that programmed memory cells are excluded from a subsequent program operation. That is, after the program voltage is applied to the memory device, a verification voltage for verifying the programming is applied to memory cells on which the program operation has been performed.

In a cell array having a 2D structure, since all word lines are arranged in a planar fashion, variation in resistance values of word lines is not significant, so that problems do not occur in a rising time of each word line. However, in a cell array having a 3D structure, a specific algorithm that is capable of compensating for variation in resistance values of word lines is needed.

Therefore, assuming that WL resistance values sequentially increase according to physical locations of word lines, a constant value of the increased resistance value is combined with a word line address, such that an optimum word-line rising time can be set.

Different bias voltages are provided to the word lines according to the set rising times for the word lines, such that the ISSP step and the program time can be uniformly applied irrespective of the locations of the word lines.

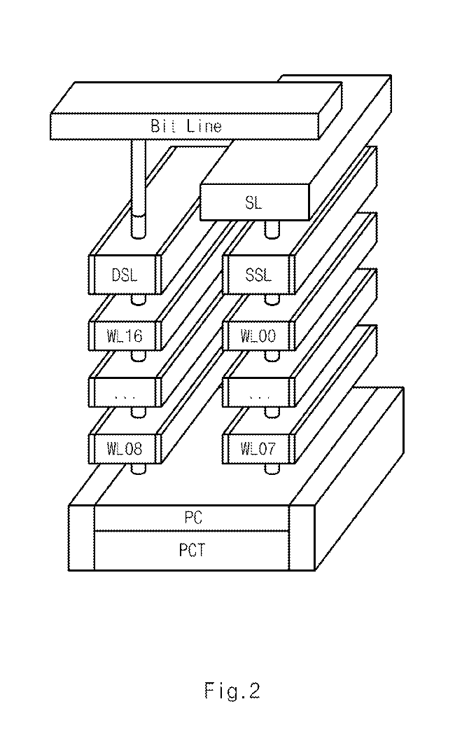

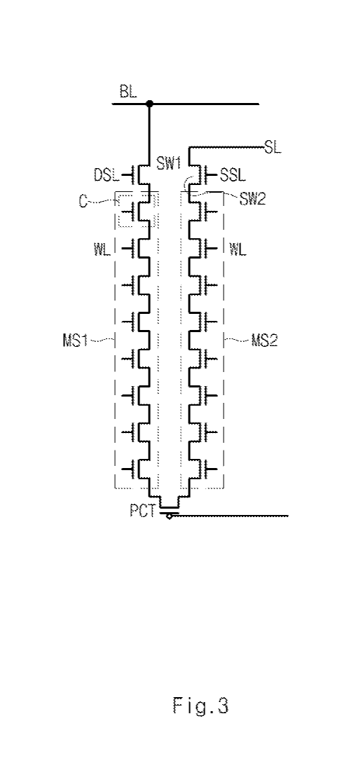

FIGS. 2 and 3 illustrate structural views of a non-volatile memory device according to an embodiment of the present invention. FIGS. 2 and 3 illustrate detailed structural views of a cell string in the cell array 100 shown in FIG. 1. As can be seen from FIGS. 2 and 3, the cell array 100 may be implemented as a 3D structure.

In the cell string of the cell array 100, source and drain terminals of a plurality of cells Cs are coupled in series to each other. A gate terminal of each cell C is coupled to a corresponding word line WL.

A switching element SW1 comprises one end coupled to one end of a first cell from among the plurality of cells Cs, and the other end coupled to a bit line BL. A gate terminal of the switching element SW1 is coupled to a drain selection line DSL.

A switching element SW2 comprises one end coupled to one end of the last cell from among the plurality of cells Cs, and the other end coupled to a source line SL. In an embodiment, a gate terminal of the switching element SW2 is coupled to a source selection line SSL.

The 3D cell array 100 is configured in the form of a U-shaped cell string comprising a first cell string MS1 and a second cell string MS2. The switching elements SW1 and SW2 are formed over the first cell string MS1 and the second cell string MS2, respectively. Compared to a vertical string structure in which the switching elements SW1 and SW2 are formed above and below a cell string, respectively, the U-shaped cell string structure has advantageous device characteristics. In order to implement the U-shaped memory cell string structure, a transistor for electrically connecting the first and second cell strings MS1 and MS2 is employed at the bottom of the U-shaped memory cell string structure. The transistor is referred to as a pipe channel transistor PCT.

Referring to FIGS. 2 and 3, the first and second cell strings MS1 and MS2 are formed over the pipe channel transistor PCT.

Each of the first string MS1 and the second string MS2 comprises a plurality of serially-coupled cells. The first string MS1 and the second string MS2 are interconnected through a pipe channel PC.

Therefore, the pipe channel transistor PCT must be turned on during a program or read operation to electrically couple the first string MS1 with the second string MS2.

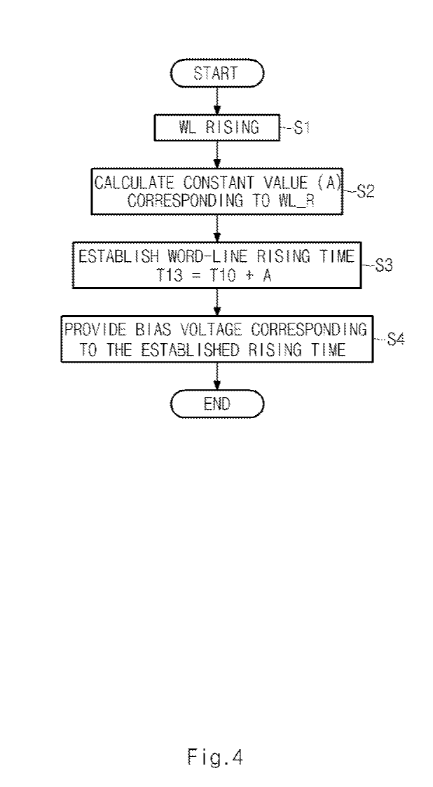

FIG. 4 is a flowchart illustrating a method for controlling a non-volatile memory device according to an embodiment of the present invention. FIG. 4 describes an algorithm for calculating a word-line rising time according to a word-line resistance value WL_R. Processes shown in FIG. 4 will be described with reference to FIG. 1.

First, a corresponding cell is selected from a cell string of the cell array 100 according to a program command and a corresponding address. Thus, a program voltage is applied to a word line WL coupled to the selected cell, so that the word line WL transitions to a rising state in step S1.

Thereafter, the constant operation unit 151 measures a WL resistance value WL_R of the word line WL, calculates a constant value A corresponding to the measured WL resistance value WL_R, and provides the constant value A to the rising-time controller 152 in step S2.

Subsequently, the rising-time controller 152 matches a word line address WL_ADD to the constant value A secured from the constant operation unit 151, and calculates a word-line rising time according to the matched result in step S3.

For example, assuming that a rising time of a word line WL0 is denoted as a predetermined reference rising time T10, a rising time T13 of a word line WL3 is calculated as follows:

T13=T10+A.

For instance, in the cell string structure shown in FIG. 3, provided that a physical location of the word line WL0 is closest to the drain selection line DSL or the source selection line SSL, the rising time T10 of the word line WL0 has the smallest value. Thus, since the word line WL3 is further away from the drain selection line DSL or the source selection line SSL, i.e., it is closer to a lowest portion of the cell string structure, the rising time T13 of the word line WL3 is greater. As a result, if the word line WL3 is located at the lowest portion of the cell string structure, the rising time T13 of the word line WL3 is determined as a sum of the smallest rising time T10 and the constant value A corresponding to the word line address WL_ADD for selecting the word line WL3.

In this embodiment, the rising time T10 of the word line WL0 located closest to the drain selection line DSL or the source selection line SSL is set to have the smallest value, and a rising time of a word line located farthest from the drain selection line DSL or the source selection line SSL is set to have the greatest value. However, in accordance with another embodiment, the word line WL0 located closest to the drain selection line DSL or the source selection line SSL is set to have the greatest value, and the rising time of the word line located farthest from the drain selection line DSL or the source selection line SSL is set to have the smallest value.

Subsequently, the voltage provider 160 provides a bias voltage corresponding to the rising time set in the rising-time controller 152 to the decoding unit 110 to drive the selected word line WL3 in step S4. In a program or verification operation of the non-volatile memory device, the bias voltage, which may be higher than the pass voltage Vpass, is applied to the selected word line WL3. In accordance with an embodiment, a voltage level of the bias voltage applied to the word line WL3 may be higher than that of a bias voltage applied to a word line whose WL resistance value is smaller than that of the word line WL3, e.g., the word line WL0. That is, as a rising time becomes longer, a bias voltage having a higher level is applied to a corresponding word line.

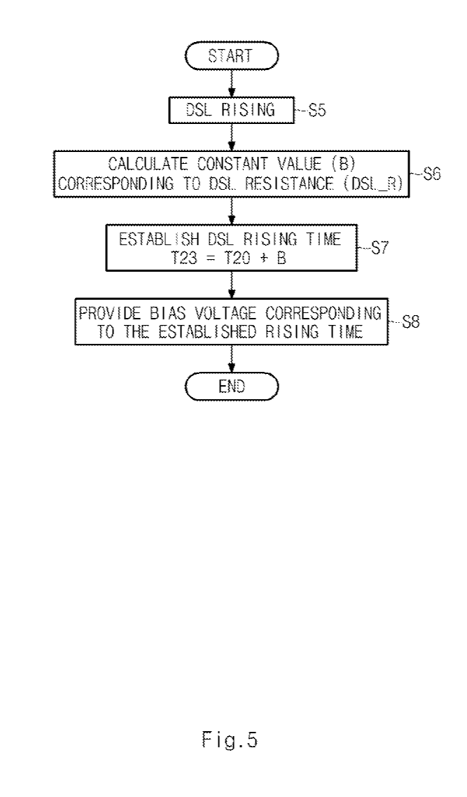

FIG. 5 is a flowchart illustrating a method for controlling a non-volatile memory device according to another embodiment of the present invention. FIG. 5 describes an algorithm for calculating a DSL rising time in response to a DSL resistance value DSL_R.

First, a cell is selected from a cell string of the cell array 100 according to a program command and a corresponding address. Thus, when the cell is selected from the cell string, a drain selection line DSL corresponding to the selected cell transitions to a rising state in step S5.

Thereafter, the constant operation unit 151 measures a DSL resistance value DSL_R of the drain selection line DSL, calculates a constant value B corresponding to the DSL resistance value DSL_R, and provides the constant value B to the rising-time controller 152 in step S6.

Subsequently, the rising-time controller 152 matches a DSL address DSL_ADD to the constant value B secured from the constant operation unit 151, and calculates a DSL rising time according to the matched result in step S7.

For example, assuming that a rising time of a drain selection line DSL0 is denoted as a predetermined reference rising time T20, a rising time T23 of a drain selection line DSL3 is calculated as follows:

T23=T20+B.

For instance, in the cell array 100, provided that a physical location of the drain selection line DSL0 is closest to an edge region of a chip, the rising time T20 of the drain selection line DSL0 has the smallest value. Thus, since the drain selection line DSL3 is further away from the edge region of the chip, i.e., it is closer to a center region of the chip, the rising time T23 of the drain selection line DSL3 is greater. As a result, if the drain selection line DSL3 is located at the center region of the chip, the rising time T23 of the drain selection line DSL3 is determined as a sum of the smallest rising time T20 and the constant value B corresponding to the drain selection address DSL_ADD for selecting the drain selection line DSL3.

In this embodiment, the rising time T20 of the drain selection line DSL0 located closest to the edge region is set to have the smallest value, and a rising time of a drain selection line located farthest from the edge region is set to have the greatest value. However, in accordance with another embodiment, the drain selection line DSL0 located closest to the edge region is set to have the greatest value, and the rising time of the drain selection line located farthest from the edge region is set to have the smallest value.

Subsequently, the voltage provider 160 provides a bias voltage corresponding to the rising time set in the rising-time controller 152 to the decoding unit 110 to drive the selected drain selection line DSL3 in step S8. In a program or verification operation of the non-volatile memory device, the bias voltage, which may be higher than the pass voltage Vpass, is applied to the selected drain selection line DSL3. In accordance with an embodiment, a voltage level of the bias voltage applied to the drain selection line DSL3 may be higher than that of a bias voltage applied to a drain selection line whose DSL resistance value is smaller than that of the drain selection line DSL3, e.g., the drain selection line DSL0. That is, as a rising time becomes longer, a bias voltage having a higher level is applied to a corresponding drain selection line.

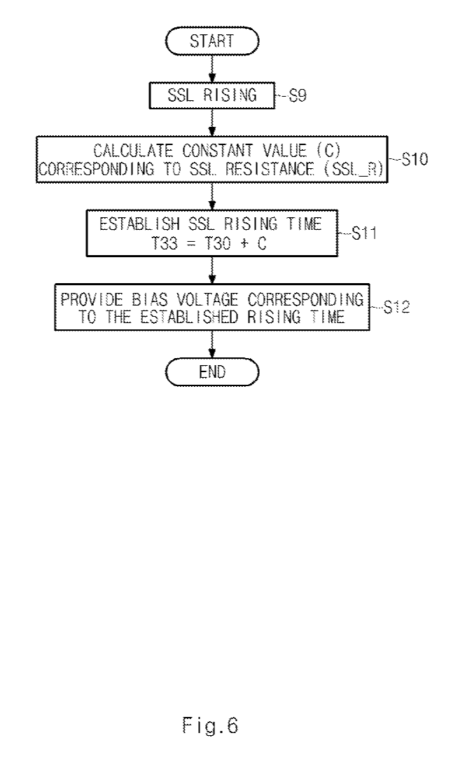

FIG. 6 is a flowchart illustrating a method for controlling a non-volatile memory device according to still another embodiment of the present invention. FIG. 6 describes an algorithm for calculating an SSL rising time in response to an SSL resistance value SSL_R.

First, a cell is selected from a cell string of the cell array 100 upon receiving a program command and a corresponding address. Thus, when the cell is selected from the cell string, a source selection line SSL corresponding to the selected cell transitions to a rising state in step S9.

Thereafter, the constant operation unit 151 measures an SSL resistance value SSL_R of the source selection line SSL, calculates a constant value C corresponding to the measured SSL resistance value SSL_R, and provides the constant value C to the rising-time controller 152 in step S10.

Subsequently, the rising-time controller 152 matches an SSL address SSL_ADD to the constant value C secured from the constant operation unit 151, and calculates an SSL rising time according to the matched result in step S11.

For example, assuming that a rising time of a source selection line SSL0 is denoted as a predetermined reference rising time T30, a rising time T33 of a source selection line SSL3 is calculated as follows:

T33=T30+C.

For instance, in the cell array 100, provided that a physical location of the source selection line SSL0 is closest to an edge region of a chip, the rising time T30 of the source selection line SSL0 has the smallest value. Thus, since the source selection line SSL3 is further away from the edge region of the chip, i.e., it is closer to a center region of the chip, the rising time T33 of the source selection line SSL3 is greater. As a result, if the source selection line SSL3 is located at the center region of the chip, the rising time T33 of the source selection line SSL3 is determined as a sum of the smallest rising time T30 and the constant value C corresponding to the source selection address SSL_ADD for selecting the source selection line SSL3.

In this embodiment, the rising time T30 of the source selection line SSL0 located closest to the edge region is set to have the smallest value, and a rising time of a source selection line located farthest from the edge region is set to have the greatest value. However, in accordance with another embodiment, the source selection line SSL0 located closest to the edge region is set to have the greatest value, and the rising time of the source selection line located farthest from the edge region is set to have the smallest value.

Subsequently, the voltage provider 160 provides a bias voltage corresponding to the rising time set in the rising-time controller 152 to the decoding unit 110 to drive the source selection line SSL3 in step S12. In a program or verification operation of the non-volatile memory device, the bias voltage, which may be higher than the pass voltage Vpass, is applied to the selected source selection line SSL3. In accordance with an embodiment, a voltage level of the bias voltage applied to the source selection line SSL3 may be higher than that of a bias voltage applied to a source selection line whose SSL resistance value is smaller than that of the source selection line SSL3, e.g., the source selection line SSL0. That is, as a rising time becomes longer, a bias voltage having a higher level is applied to a corresponding source selection line.

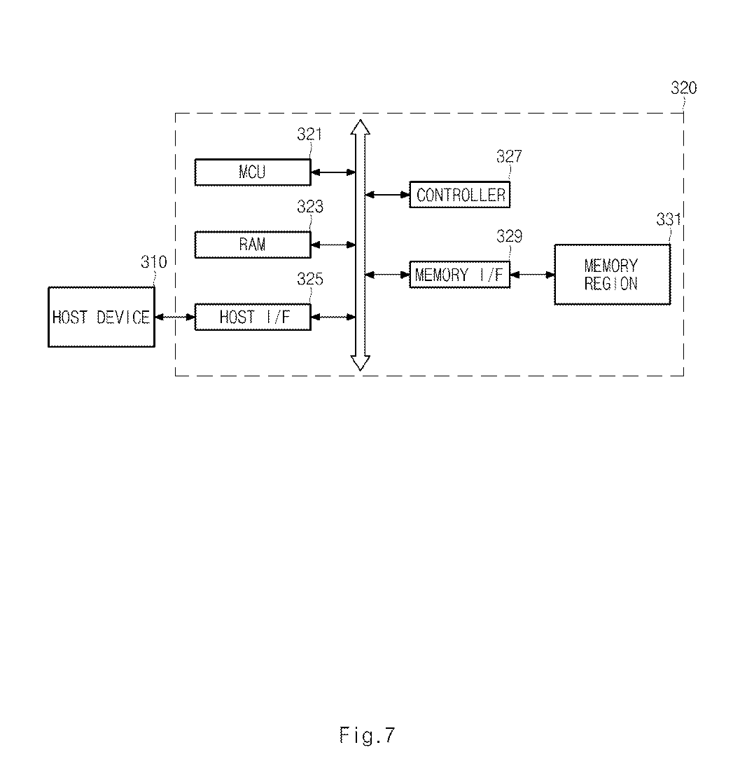

FIG. 7 is a block diagram illustrating a data processing system configured to use a non-volatile memory device according to an embodiment of the present invention.

Referring to FIG. 7, the data processing system comprises a host device 310 and a non-volatile memory device 320. The non-volatile memory device 320 comprises a micro controller unit (MCU) 321, a RAM 323 serving as an operation memory, a host interface (I/F) 325, a controller 327, a memory interface (I/F) 329, and a memory region 331.

In an embodiment, the MCU 321 provides overall control to the non-volatile memory device 320, and firmware or an application may be loaded on the RAM 323 and then executed.

The RAM 323 is used to temporarily store data needed for operating the MCU 321. Under the control of the MCU 321, the RAM 323 temporarily stores data from the memory region 331 and then provides the stored data to the host device 310, or temporarily stores data from the host device 310 and then provides the stored data to the memory region 331.

The host interface 325 may control data exchange between the host device 310 and the memory region 331, and may provide a protocol conversion function as necessary.

The controller 327 is coupled to the memory region 331 through the memory interface 329. The controller 327 may provide a command signal, an address, a control signal, and data for controlling operations of the memory region 331.

Specifically, the controller 327 according to an embodiment of the present invention determines a rising time of a selected word line because a specific word line is selected in response to a program command and a corresponding address, such that a specific bias voltage is applied for the determined rising time.

In addition, the controller 327 according to another embodiment of the present invention determines a rising time of a selected drain selection line DSL or source selection line SSL because a specific SDL or SSL is selected in response to the program command and a corresponding address, such that a specific bias voltage is applied for the determined rising time.

In accordance with an embodiment of the present invention, the controller 327 may comprise the rising-time controller 152 and the constant operation unit 151 shown in FIG. 1. The constant operation unit 151 may be located outside the rising-time controller 152.

In more detail, the controller 327 measures different resistance values of individual word lines during a test mode, predicts a constant value corresponding to each of the resistance values of the word lines, and stores the predicted constant values in a storage unit (not shown). Upon receiving a corresponding address and the program command from an external node, the controller 327 sets a rising time of a selected word line corresponding to the address by referring to a constant value of the selected word line. In addition, the controller 327 applies a bias voltage corresponding to the set rising time to the memory region 331 during a corresponding time.

In addition, the controller 327 measures a resistance value for each of drain selection lines DSLs or each of source selection lines SSLs during the test mode, predicts a constant value corresponding to each of the resistance values of the drain selection lines DSL or the source selection lines SSL, and stores the predicted constant values in a storage unit (not shown). Upon receiving a corresponding address and the program command from the external node, the controller 327 sets a rising time of a selected DSL or SSL corresponding to the address by referring to a constant value of the selected DSL or SSL. In addition, the controller 327 applies a bias voltage corresponding to the set rising time to the memory region 331 during a corresponding time.

For example, the controller 327 is configured to control the rising time using substantially the same structure and operation as those of FIGS. 2 to 6, and thus a detailed description thereof will be omitted for simplicity of description.

A cell array of the memory region 331 may be composed of 2D or 3D non-volatile memory cells, and may comprise at least one plane or at least one chip comprising a plurality of banks.

The scope and spirit of the non-volatile memory device 320 is not limited thereto, and the non-volatile memory device 320 may further comprise an additional device or configuration according to a system environment to be applied. For example, the non-volatile memory device 320 may further comprise a ROM for storing data needed for an initial booting operation or an error correction unit. If necessary, the non-volatile memory device 320 may further comprise a power-supply unit, a communication module, etc.

The non-volatile memory device 320 may be packaged as a memory card. In addition, in accordance with another embodiment of the present invention, the data processing system may further comprise a separate application chipset such as a camera module.

As is apparent from the above description, a rising time changes according to locations of word lines, drain selection lines, and source selection lines, so that a difference between program times determined according to the locations can be minimized.

Those skilled in the art will appreciate that the present invention may be carried out in other specific ways than those set forth herein without departing from the spirit and essential characteristics of the present invention. The above exemplary embodiments are therefore to be construed in all aspects as illustrative and not restrictive. The scope of the invention should be determined by the appended claims and their legal equivalents, not by the above description, and all changes coming within the meaning and equivalency range of the appended claims are intended to be embraced therein. Also, it is obvious to those skilled in the art that claims that are not explicitly cited in each other in the appended claims may be presented in combination as an exemplary embodiment of the present invention or comprised as a new claim by a subsequent amendment after the application is filed.

Although a number of illustrative embodiments consistent with the invention have been described, it should be understood that numerous other modifications and embodiments can be devised by those skilled in the art that will fall within the spirit and scope of the principles of this disclosure. Particularly, numerous variations and modifications are possible in the component parts and/or arrangements which are within the scope of the disclosure, the drawings and the accompanying claims. In addition to variations and modifications in the component parts and/or arrangements, alternative uses will also be apparent to those skilled in the art.

What is claimed is:

1. A non-volatile memory device comprising:
a cell array comprising a plurality of cells each of which is coupled to and disposed between a word line and a bit line;
a drive controller configured to secure a constant value corresponding to a selected word line, which is determined by detecting a variation in word-line resistance values measured according to locations of word lines in the cell array, and set a rising time of the selected word line using the constant value; and
a voltage provider configured to provide the selected word line with a bias voltage obtained in response to the rising time set in the drive controller.

2. The non-volatile memory device according to claim 1, wherein the drive controller comprises:
a constant operation unit configured to secure the constant value corresponding to the selected word line; and
a rising-time controller configured to set the rising time of the selected word line by matching an address for the selected word line with the constant value from the constant operation unit and combining the constant value with a predetermined rising time.

3. The non-volatile memory device according to claim 2, wherein the predetermined rising time correspond to the smallest one of rising times corresponding to the word lines.

4. The non-volatile memory device according to claim 1, wherein the drive controller is configured to set the rising time of the selected word line on the basis of a physical distance between the selected word line and at least one of a corresponding drain selection line and a corresponding source selection line comprised in the cell array.

5. The non-volatile memory device according to claim 1, wherein the cell array comprises a three-dimensional (3D) cell array structure.

6. The non-volatile memory device according to claim 1, wherein the cell array comprises a two-dimensional (2D) cell array structure.

7. A non-volatile memory device comprising:
a cell array comprising a plurality of cells coupled to drain selection lines;
a drive controller configured to secure a constant value corresponding to a selected drain selection line, which is determined by detecting a variation in data-selection-line resistance values measured according to locations of the drain selection lines, and set a rising time of the selected drain selection line using the constant value; and
a voltage provider configured to provide the selected drain selection line with a bias voltage obtained in response to the rising time set in the drive controller.

8. The non-volatile memory device according to claim 7, wherein the drive controller comprises:
a constant operation unit configured to secure the constant value corresponding to the selected drain selection line; and
a rising-time controller configured to set the rising time of the selected drain selection line by matching an address for the selected drain selection line with the constant value from the constant operation unit and combining the constant value with a predetermined rising time.

9. The non-volatile memory device according to claim 8, wherein the predetermined rising time corresponds to the smallest one of rising times corresponding to the drain selection lines.

10. The non-volatile memory device according to claim 7, wherein the drive controller is configured to set the rising time of the selected drain selection line on the basis of a physical distance between the drain selection lines in the cell array.

11. The non-volatile memory device according to claim 7, wherein the cell array comprises a three-dimensional (3D) cell array structure.

12. The non-volatile memory device according to claim 7, wherein the cell array comprises a two-dimensional (2D) cell array structure.

13. A non-volatile memory device comprising:
a cell array comprising a plurality of cells each coupled to a corresponding source selection line;
a drive controller configured to secure a constant value corresponding to a selected source selection line, which is determined by

18. The non-volatile memory device according to claim 13, wherein the cell array comprises a two-dimensional (2D) cell array structure.

19. A method for controlling a non-volatile memory device, the method comprising:
measuring a word-line resistance value for each of word lines disposed at different locations, and calculating a constant value of each of the word lines by detecting a variation in the word-line resistance values;
setting a rising time of a selected word line by matching an address for the selected word line with a corresponding constant value and combining the corresponding constant value with a predetermined rising time; and
providing a bias voltage corresponding to the selected word line to a cell array in response to the set rising time.

20. The method according to claim 19, wherein the constant values of the word lines are determined according to the locations of the word lines with respect to at least one of a corresponding drain selection line and a corresponding source selection line.

21. A method for controlling a non-volatile memory device, the method comprising:
measuring a data-selection-line resistance value for each of drain selection lines disposed at different locations, and calculating a constant value of each of the drain selection lines by detecting a variation in the data-selection-line resistance values;
setting a rising time of a selected drain selection line by matching an address for the selected drain selection line with a corresponding constant value and combining the corresponding constant value with a predetermined rising time; and
providing a bias voltage corresponding to the selected drain selection line to a cell array in response to the set rising time.

22. The method according to claim 21, wherein the constant values of the drain selection lines are determined according to the locations of the drain selection lines with respect to an edge region or a center region of a chip.

23. A method for controlling a non-volatile memory device, the method comprising:
measuring a source-selection-line resistance value for each of source selection lines disposed at different locations, and calculating a constant value of each of the source selection lines by detecting a variation in the source-selection-line resistance values;
setting a rising time of a selected source selection line by matching an address for the selected source selection line with a corresponding constant value and combining the corresponding constant value with a predetermined rising time; and
providing a bias voltage corresponding to the selected source selection line to a cell array in response to the set rising time.

24. The method according to claim 23, wherein the constant values of the source selection lines are determined according to the locations of the source selection lines with respect to an edge region or a center region of a chip.

25. A data processing system comprising:
a host device; and
a non-volatile memory device coupled to the host device through a host interface,
wherein the non-volatile memory device comprises a controller that is configured to secure a constant value corresponding to a selected word line, which is determined by detecting a variation in word-line resistance values measured according to locations of word lines, set a rising time of the selected word line using the constant value, and provide a bias voltage corresponding to the selected word line to a cell array in response to the set rising time.

26. The data processing system according to claim 25, wherein the controller comprises:
a drive controller configured to secure the constant value of the selected word line, which is determined by detecting the variation in the word-line resistance values, and set a rising time of the selected word line using the constant value; and
a voltage provider configured to provide the bias voltage to the cell array in response to the rising time set in the drive controller.

27. The data processing system according to claim 26, wherein the drive controller comprises:
a constant operation unit configured to secure the constant value corresponding to the selected word line, which is obtained by detecting the variation in the word-line resistance values; and
a rising-time controller configured to set the rising time of the selected word line by matching an address for the selected word line with the constant value from the constant operation unit and combining the constant value with a predetermined rising time.

28. The data processing system according to claim 27, wherein the predetermined rising time corresponds to the smallest one of rising times corresponding to the word lines.

29. The data processing system according to claim 25, wherein the non-volatile memory device further comprises a memory region that is configured in the form of a three-dimensional (3D) cell array structure.

30. The data processing system according to claim 25, wherein the non-volatile memory device further comprises a memory region that is configured in the form of a two-dimensional (2D) cell array structure.
